(19) United States
(12) Patent Application Publication
(10) Pub. No.: US 2012/0322249 A1
(43) Pub. Date: Dec. 20, 2012

(54) MANUFACTURING METHOD OF SEMICONDUCTOR STRUCTURE

(75) Inventors: Jui-Chin Chen, Hsinchu County (TW); Cha-Hsin Lin, Tainan City (TW); John H. Lau, Taipei City (TW); Tzu-Kun Ku, Hsinchu City (TW)

(73) Assignee: INDUSTRIAL TECHNOLOGY RESEARCH INSTITUTE, Hsinchu (TW)

(21) Appl. No.: 13/596,079

(22) Filed: Aug. 28, 2012

Related U.S. Application Data
(62) Division of application No. 12/967,071, filed on Dec. 14, 2010.

(30) Foreign Application Priority Data
Nov. 12, 2010 (TW) 99139030

(51) Int. Cl. H01L 21/306

(52) U.S. Cl. 438/584; 257/E21.219

(57) ABSTRACT

In a manufacturing method of a semiconductor structure, a substrate having a front surface and a back surface is provided. The front surface has a device layer thereon and conductive plugs electrically connected to the device layer. A thinning process is performed on the back surface of the substrate, such that the back surface of the substrate and surfaces of the conductive plugs have a distance therebetween. Holes are formed in the substrate from the back surface to the conductive plugs, so as to form a porous film. An oxidization process is performed, such that the porous film correspondingly is reacted to form an oxide material layer. A polishing process is performed on the oxide material layer to expose the surfaces of the conductive plugs.

### CROSS-REFERENCE TO RELATED APPLICATION

This application is a Divisional of and claims the priority benefit of U.S. patent application Ser. No. 12/967,071, filed on Dec. 14, 2010, now pending, which claims the priority benefits of Taiwan application Serial No. 99139030, filed on Nov. 12, 2010. The entirety of the above-mentioned patent applications is hereby incorporated by reference herein and made a part of specification.

### TECHNICAL FIELD

The disclosure relates to a semiconductor structure and a manufacturing method thereof, and more particularly to a wafer structure and a manufacturing method thereof.

### BACKGROUND

In recent years, with the rapid development of the semiconductor process, the increase in the complexity of IC design, and the demand for circuit performance, the integration of three dimensional (3D) IC circuits has been developed to reduce the length of connection wires and the RC delay, such that the circuit performance can be improved. At present, conductive plugs are normally connected between each wafer or each chip through applying a through-silicon via (TSV) technology. Specifically, the conductive plugs connected between the chips or the wafers contribute to vertical electrical connection of the chips or the wafers.

In the TSV technology, a plurality of conductive plugs are formed in a wafer, and a thinning process is performed on a back surface of the wafer, such that the conductive plugs penetrate the entire wafer. However, the conductive plugs are generally made of metal copper, and copper ions and/or copper atoms are very much likely to diffuse into the silicon wafer while the thinning process is performed on the back surface of the wafer to expose the conductive plugs made of the copper material. Thereby, the wafer is contaminated by the copper ions and/or copper atoms, and device operation on the wafer is affected.

### SUMMARY

The disclosure provides a manufacturing method of a semiconductor structure. In the manufacturing method, a substrate having a front surface and a back surface is provided. The front surface has a device layer thereon and a plurality of conductive plugs electrically connected to the device layer. A thinning process is performed on the back surface of the substrate, such that the back surface of the substrate and surfaces of the conductive plugs have a distance therebetween. A plurality of holes are formed in the substrate from the back surface to the conductive plugs, so as to form a porous film. An oxidization process is performed, such that the porous film is correspondingly reacted to form an oxide material layer. A polishing process is performed on the oxide material layer to expose the surfaces of the conductive plugs.

The disclosure further provides a semiconductor structure that includes a substrate, an oxide material layer, and a plurality of conductive plugs. The substrate has a front surface and a back surface, and the front surface of the substrate has a device layer. The oxide material layer is located on the back surface of the substrate and has a top surface. The conductive plugs penetrate the substrate and the oxide material layer. Each of the conductive plugs has a top surface and a bottom surface, and the top surface of each of the conductive plugs and the top surface of the oxide material layer are coplanar.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1A to FIG. 1E are schematic cross-sectional flow charts illustrating a manufacturing method of a semiconductor structure according to an embodiment.

FIG. 2A to FIG. 2D are partially enlarged views of FIG. 1B to FIG. 1D according to an embodiment.

FIG. 3A to FIG. 3D are partially enlarged views of FIG. 1B to FIG. 1D according to another embodiment.

FIG. 4 is a schematic view illustrating an electro-chemical reaction apparatus according to an embodiment.

### DETAILED DESCRIPTION OF DISCLOSED EMBODIMENTS

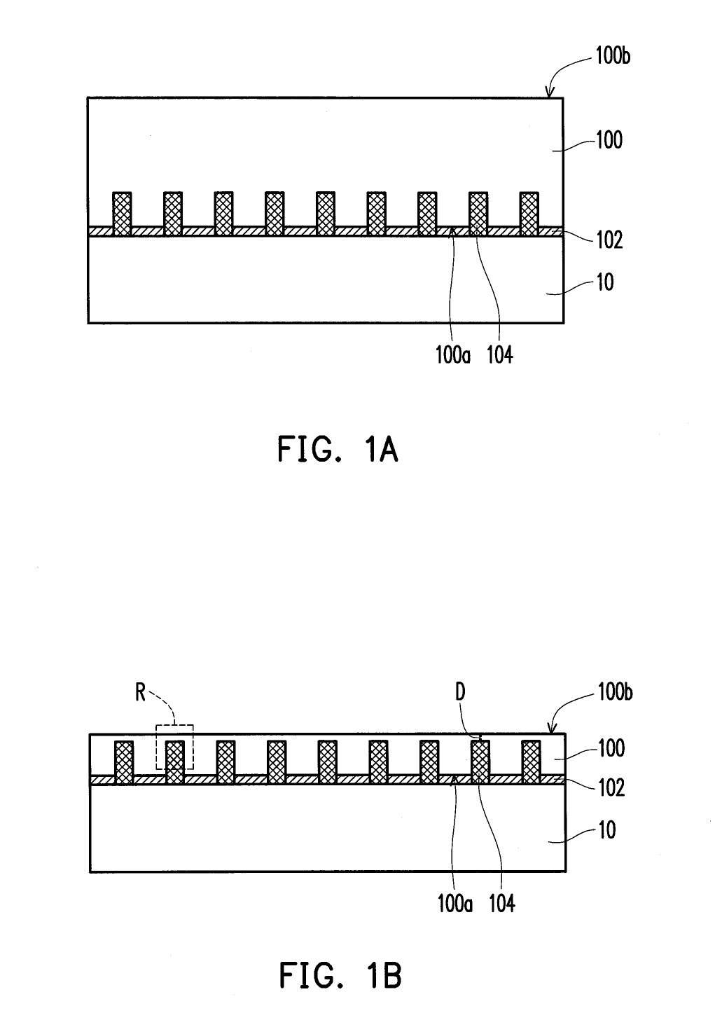

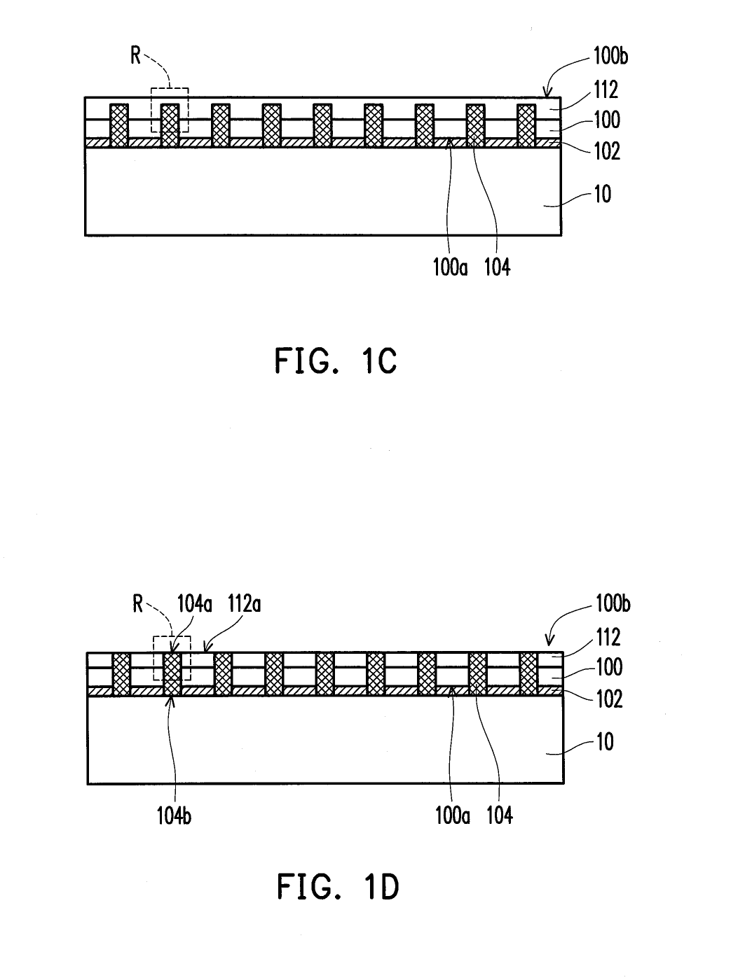

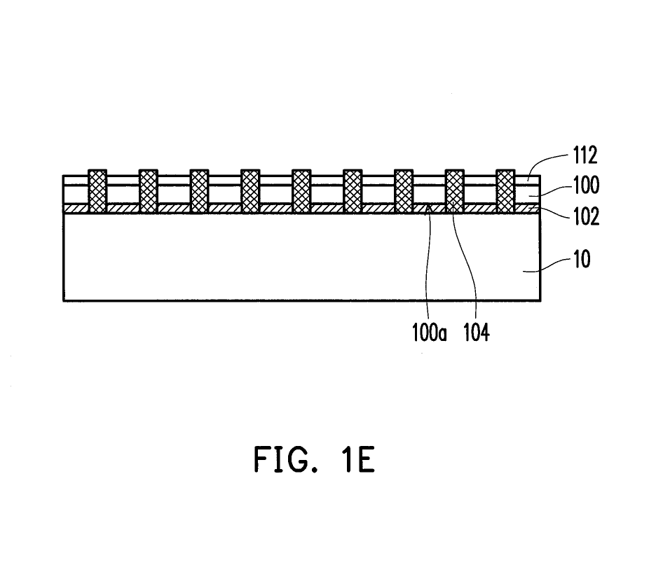

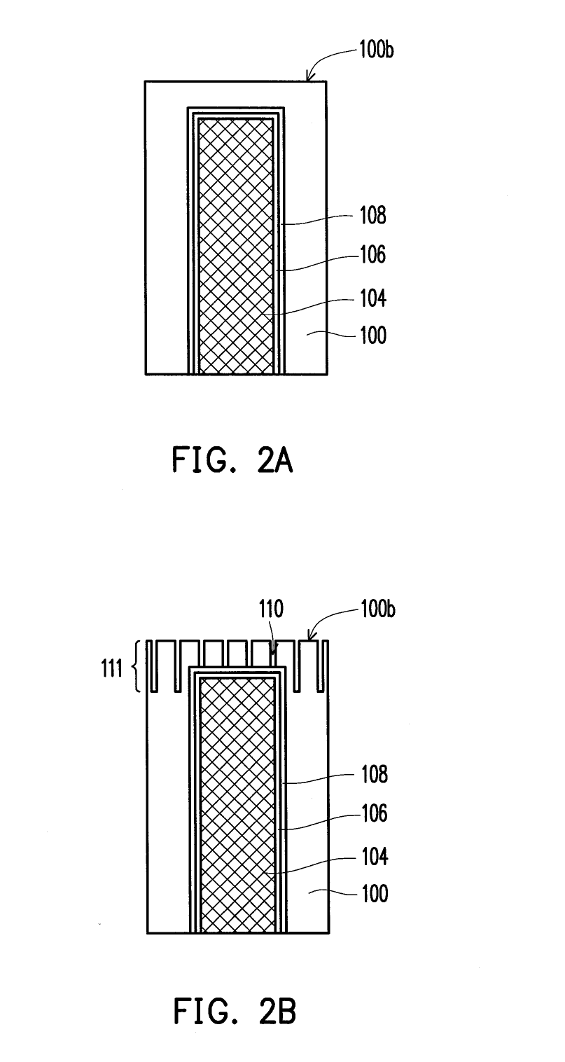

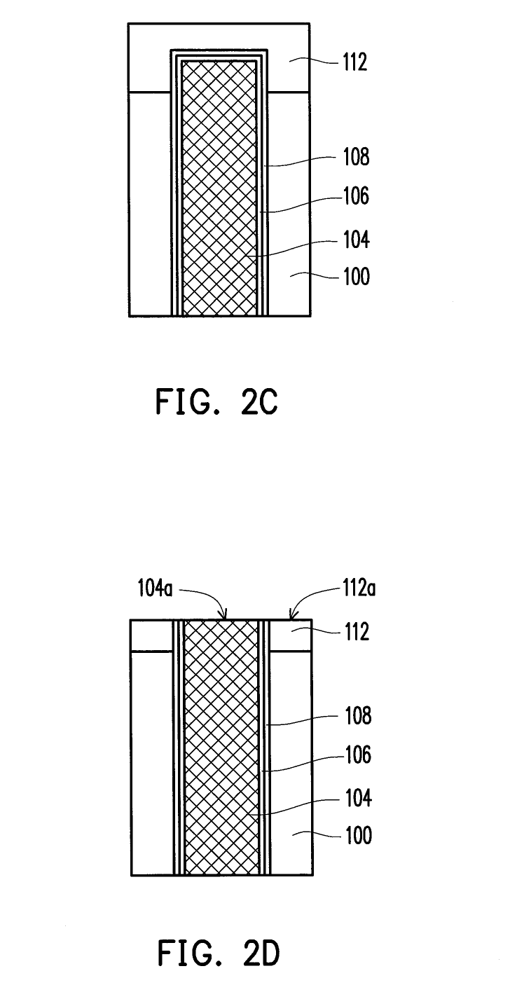

FIG. 1A to FIG. 1E are schematic cross-sectional flow charts illustrating a manufacturing method of a semiconductor structure according to an embodiment. FIG. 2A to FIG. 2D are partially enlarged views of FIG. 1B to FIG. 1D according to an embodiment.

With reference to FIG. 1A, in the manufacturing method, a substrate 100 is provided. Here, the substrate 100 can be a silicon wafer or a silicon chip. The substrate 100 has a front surface 100a and a back surface 100b. The front surface 100a of the substrate 100 has a device layer 102 thereon and a plurality of conductive plugs 104 electrically connected to the device layer 102. According to an embodiment, the device layer 102 includes logic circuits, memory devices, display devices, other semiconductor devices, or a combination thereof, for example. The conductive plugs 104 are formed in the substrate 100 and extend from the front surface 100a of the substrate 100 to the inside of the substrate 100. In general, the conductive plugs 104, for instance, are formed by performing an etching process, a laser drilling process, or any other appropriate process to form openings in the substrate 100 and filling the openings with a conductive material to form the conductive plugs 104. In consideration of electrical conductivity, the conductive plugs 104 are preferably made of metal, such as copper or other metallic materials.

After the device layer 102 and the conductive plugs 104 are formed on the substrate 100, the substrate 100 is placed on a support plate 10, so as to proceed to subsequent manufacturing processes. The following manufacturing processes include several steps of processing the back surface 100b of the substrate 100. Therefore, the front surface 100a of the substrate 100 faces the support plate 10 after the substrate 100 is placed on the support plate 10, such that the back surface 100b of the substrate 100 is exposed.

As indicated in FIG. 1B, a thinning process is performed on the back surface 100b of the substrate 100, and the back surface 100b of the substrate 100 and surfaces of the conductive plugs 104 have a distance D therebetween after the thinning process is performed. Namely, the thinning process of this embodiment is performed on the back surface 100b of the substrate 100 to some degree, such that the conductive plugs 104 are not exposed after the thinning process is performed. Here, the distance D between the back surface 100b of the substrate 100 and the surfaces of the conductive plugs 104 is about 1 um to about 3 um, for instance. The thinning process is, for instance, a grinding process or any other appropriate process.

The structure on which the aforesaid thinning process is performed is shown in FIG. 1B, and FIG. 2A is an enlarged view of the area R. With reference to FIG. 1B and FIG. 2A, in this embodiment, a barrier layer 106 can be further formed on side surfaces of the conductive plugs 104 in this embodiment, and the barrier layer 106 can be made of titanium (Ti), tantalum (Ta), or any other appropriate barrier material. Besides, an isolation layer 108 can be formed on the barrier layer 106, and the isolation layer 108 is made of silicon oxide, silicon oxynitride, or any other isolation material, for instance. In this embodiment, while the conductive plugs 104 are formed, the method of forming the barrier layer 106 and the isolation layer 108 on the side surfaces of the conductive plugs 104 includes forming the openings in the substrate 100, sequentially forming the isolation layer 108 and the barrier layer 106 on surfaces of the openings, and filling the openings with the conductive material to form the conductive plugs 104 as well as the barrier layer 106 and the isolation layer 108 that are located on the side surfaces of the conductive plugs 104.

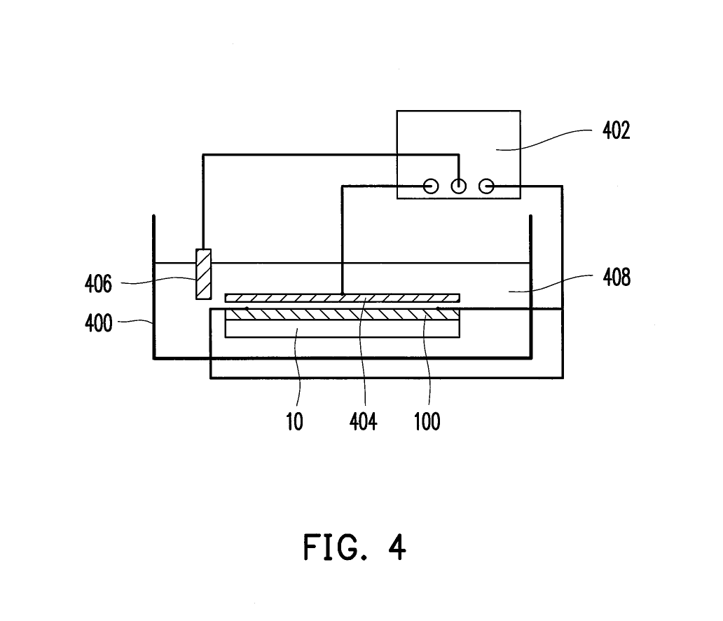

With reference to FIG. 2B, a plurality of holes 110 are formed in the substrate 100 from the back surface 100b of the substrate 100 to the conductive plugs 104, so as to form a porous film 111. In this embodiment, the porous film 111 is formed by performing an electro-etching process. The electro-etching process can be implemented with use of the electro-chemical reaction apparatus shown in FIG. 4. The electro-chemical reaction apparatus includes a solution storage tank 400, a reaction solution 408 stored in the solution storage tank 400, an electrode plate 404, a reference electrode 406, and a controller 402. When the electro-etching process is to be performed, the substrate 100 (as shown in FIG. 1B) on the support plate 10 is moved to the solution storage tank 400 and is completely immersed into the reaction solution 408. Here, the reaction solution 408 is an etchant that can include hydrofluoric acid, hydrofluoric acid containing an oxidizing agent, or any other etchant. The concentration of the hydrofluoric acid is about 2% to about 20%.

The controller 402 applies a voltage respectively to the electrode plate 404 and the substrate 100, such that the electrode plate 404 acts as the cathode, and that the substrate 100 acts as the anode. Since the difference in potential between the electrode plate 404 and the substrate 100 is sufficient, the electro-etching (electro-oxidization) process can be performed on the substrate 100 with use of the etchant 408. Thereby, the holes 110 (i.e., the porous film 111) are formed on the back surface 100b of the substrate 100. To be more specific, during the electro-etching process, the back surface 100b of the substrate 100 is etched by the etchant 408 along a crystal orientation direction of the substrate 100 to form the holes 110 (the porous film 111). The electro-etching process is performed for about 2 minutes to about 60 minutes at the normal temperature. In this embodiment, since the back surface 100b of the substrate 100 can be etched by the etchant 408 along a specific crystal orientation direction of the substrate 100 in the electro-etching (electro-oxidization) process, the holes 110 extending from the back surface 100b to the inside of the substrate 100 can be formed in the substrate 100. In this embodiment, the diameter of the holes 110 is about 0.001 um to about 1 um, and the depth of the holes 110 is about 0.5 um to about 10 um.

After the porous film 111 is formed, an oxidization process is performed, such that the porous film 111 correspondingly reacts to form the oxide material layer 112, as shown in FIG. 1C and FIG. 2C. In this embodiment, the oxidization process refers to the electro-oxidization process. Similarly, the electro-oxidization process is implemented with use of the electro-chemical reaction apparatus shown in FIG. 4. To be more specific, when the electro-oxidization process is to be performed, the substrate 100 (as shown in FIG. 2B) on the support plate 10 is moved to the solution storage tank 400 and is completely immersed into the reaction solution 408. Here, the reaction solution 408 stored in the solution storage tank 400 is an alkaline solution having the concentration from about 0.001 M to about 1 M. The alkaline solution can include sodium hydroxide, potassium hydroxide, ammonium hydroxide, or any other alkaline solution. The controller 402 applies a voltage respectively to the electrode plate 404 and the substrate 100, and thereby the potential of the substrate 100 and the potential of the alkaline solution 408 are different. The voltage dissociates the water molecules of the alkaline solution 408 into a number of hydrogen ions (H⁺) and hydroxyl ions (OH⁻). Meanwhile, the surface potential of the substrate 100 is increased. Due to the electric field, the hydroxyl ions (OH⁻) enter the holes 110 of the porous film 111 and react with the silicon substrate 100, so as to form the oxide material layer 112.

The structure on which the aforesaid electro-oxidization process is performed is shown in FIG. 1C and FIG. 2C, and FIG. 2C is an enlarged view of the area R depicted in FIG. 1C. With reference to FIG. 1C and FIG. 2C, since the porous film 111 is reacted to form the oxide material layer 112, the oxide material layer 112 can completely cover the conductive plugs 104 close to the back surface 100b of the substrate 100.

A polishing process is performed on the oxide material layer 112, such that the surfaces of the conductive plugs 104 are exposed, as shown in FIG. 1D and FIG. 2D. The polishing process in this embodiment is a chemical-mechanical polishing process, for instance.

The structure formed by conducting the aforesaid manufacturing method is illustrated in FIG. 1D and FIG. 2D and includes the substrate 100, the oxide material layer 112, and the conductive plugs 104. The substrate 100 has the front surface 100a and the back surface 100b, and the front surface 100a of the substrate 100 has the device layer 102. The oxide material layer 112 is located on the back surface 100b of the substrate 100 and has a top surface 112a. The conductive plugs 104 penetrate the substrate 100 and the oxide material layer 112, and each of the conductive plugs 104 has the top surface 104a and the bottom surface 104b. Specifically, the top surface 104a of each of the conductive plugs 104 and the top surface 112a of the oxide material layer 112 are coplanar.

According to an embodiment, the barrier layer 106 is further formed on side surfaces of the conductive plugs 104. The barrier layer 106 can further include the isolation layer 108 thereon. The barrier layer 106 and the isolation layer 108 cover the side surfaces of the conductive plugs 104. Namely, the top surfaces 104a and the bottom surfaces 104b of the conductive plugs 104 are not covered by the substrate 100. The uncovered top surfaces 104a and bottom surfaces 104b of the conductive plugs 104 are to be electrically connected to other wafers or chips in subsequent processes.

If the polishing process is performed for a long period of time, the oxide material layer 112 can be removed to a great extent, so as to form the structure shown in FIG. 1E. Namely, in FIG. 1E, both the top surfaces 104a of the conductive plugs 104 and a portion of the side surfaces close to the top surfaces 104a of the conductive plugs 104 are exposed.

In the embodiment described above, the oxide material layer 112 is formed by performing the electro-etching process as illustrated in FIG. 2B and the electro-oxidization process as illustrated in FIG. 2C. However, the disclosure is not limited thereto. The oxide material layer 112 can be formed in other way according to this disclosure, as described hereinafter.

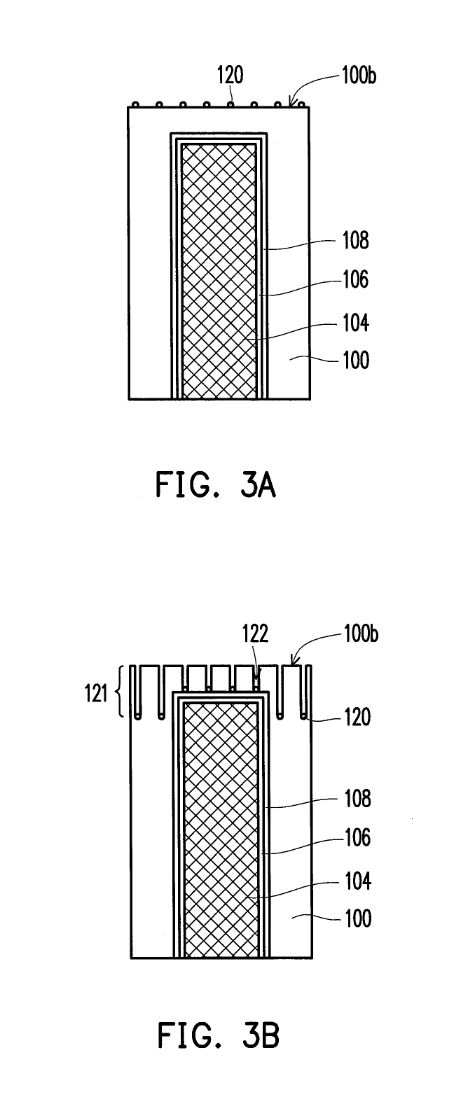

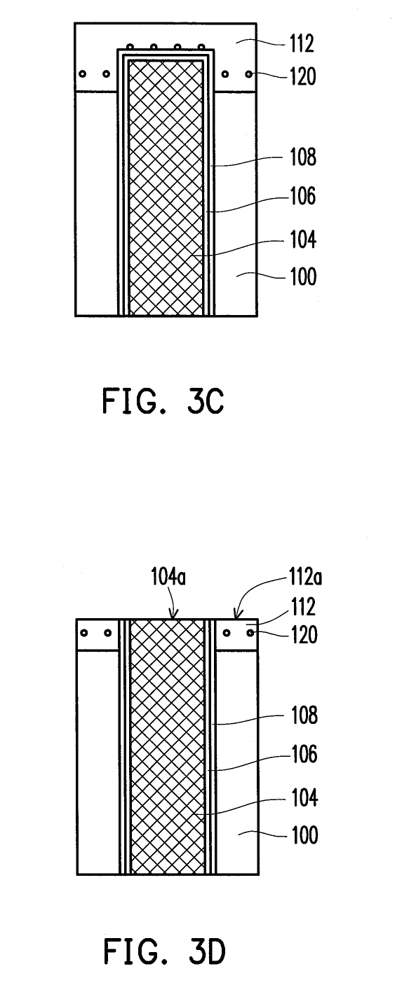

Please refer to FIG. 3A which is a partially enlarged view of the area R shown in FIG. 1B. In this embodiment, after the thinning process is performed on the back surface 100b of the substrate 100, a plurality of conductive particles 120 are formed on the back surface 100b of the substrate 100. Here, the diameter of the conductive particles 120 is about 0.001 um to about 0.1 um, for instance, and the conductive particles 120 are preferably made of the same material as that of the barrier layer 106, e.g., Ti or Ta. The conductive particles 120 can be formed by performing a chemical displacement process. The chemical displacement process is performed on condition that the back surface 100b of the substrate 100 is exposed to a TaClx-containing water solution or a TiCly-containing water solution at about 20° C. to about 60° C. for about 1 minute to about 30 minutes. Here, x=2˜5, and y=2˜4. The back surface 100b of the substrate 100 is then washed with use of water, and the chemical displacement process is completed.

The electro-etching process is performed on the structure shown in FIG. 3A. The electro-oxidization process is implemented with use of the electro-chemical reaction apparatus shown in FIG. 4. When the electro-etching process is to be performed, the support plate 10 and the substrate 100 (as shown in FIG. 3A) on the support plate 10 are moved to the solution storage tank 400, and the substrate 100 is completely immersed into the reaction solution 408. Here, the reaction solution 408 is the etchant with the concentration from about 2% to about 20%, and the etchant can include hydrofluoric acid, hydrofluoric acid containing an oxidizing agent, or any other etchant.

The controller 402 applies a voltage respectively to the electrode plate 404 and the substrate 100, such that the electrode plate 404 acts as the cathode, and that the substrate 100 acts as the anode. The difference in potential between the electrode plate 404 and the substrate 100 is sufficient, and the potential of the conductive particles 120 and the potential of the substrate 100 also have the difference due to the difference in materials. Hence, when the electro-etching process is performed, the conductive particles 120 and the substrate 100 in the etchant have the chemical potential difference therebetween, and therefore the etching process starts from the conductive particles 120 to the inside of the substrate 100. Thereby, the holes 122 are formed in the substrate 100. There are conductive particles 120 located at the bottoms of the holes 122. In this embodiment, the electro-etching process is performed for about 2 minutes to about 60 minutes at the normal temperature. Besides, according to this embodiment, the diameter of the holes 122 is about 0.001 um to about 1 um, and the depth of the holes 122 is about 0.5 um to about 15 um.

After the porous film 121 is formed, an oxidization process is performed, such that the porous film 121 correspondingly reacts to form the oxide material layer 112, as shown in FIG. 3C. In this embodiment, the oxidization process refers to the electro-oxidization process. Similarly, the electro-oxidization process is implemented with use of the electro-chemical reaction apparatus shown in FIG. 4. To be more specific, when the electro-oxidization process is to be performed, the support plate 10 and the substrate 100 (as shown in FIG. 3B) on the support plate 10 are moved to the solution storage tank 400, and the substrate 100 is completely immersed into the reaction solution 408. Here, the reaction solution 408 is an alkaline solution having the concentration from about 0.001 M to about 1 M. The alkaline solution can include sodium hydroxide, potassium hydroxide, ammonium hydroxide, or any other alkaline solution. The controller 402 applies a voltage respectively to the electrode plate 404 and the substrate 100, and thereby the potential of the substrate 100 and the potential of the alkaline solution 408 are different. The voltage dissociates the water molecules of the alkaline solution into a number of hydrogen ions (H⁺) and hydroxyl ions (OH⁻). Meanwhile, the surface potential of the substrate 100 is increased. Due to the electric field, the hydroxyl ions (OH⁻) enter the holes 122 and react with the silicon substrate 100, so as to form the oxide material layer 112.

The structure on which the aforesaid electro-oxidization process is performed is shown in FIG. 1C and FIG. 3C, and FIG. 3C is an enlarged view of the area R depicted in FIG. 1C. With reference to FIG. 1C and FIG. 3C, since the porous film 121 reacts to form the oxide material layer 112, the oxide material layer 112 can cover the conductive plugs 104 close to the back surface 100b of the substrate 100. Specifically, in this embodiment, the porous film 121 has the conductive particles 120. Hence, when the electro-oxidization process is subsequently performed, and the porous film 121 is correspondingly reacted to form the oxide material layer 112, the oxide material layer 112 still has the remaining conductive particles 120 therein.

A polishing process is performed on the oxide material layer 112, such that the surfaces of the conductive plugs 104 are exposed, as shown in FIG. 1D and FIG. 3D. The polishing process in this embodiment is a chemical-mechanical polishing process, for instance.

The structure formed by conducting the aforesaid manufacturing method is illustrated in FIG. 1D and FIG. 3D and includes the substrate 100, the oxide material layer 112, and the conductive plugs 104. The substrate 100 has the front surface 100a and the back surface 100b, and the front surface 100a of the substrate 100 has the device layer 102. The oxide material layer 112 is located on the back surface 100b of the substrate 100 and has a top surface 112a. The conductive plugs 104 penetrate the substrate 100 and the oxide material layer 112, and each of the conductive plugs 104 has the top surface 104a and the bottom surface 104b. Specifically, the top surface 104a of each of the conductive plugs 104 and the top surface 112a of the oxide material layer 112 are coplanar, and the oxide material layer 112 has the conductive particles 120.

According to an embodiment of the disclosure, the barrier layer 106 is further formed on side surfaces of the conductive plugs 104. The barrier layer 106 can further include the isolation layer 108 thereon. The barrier layer 106 and the isolation layer 108 cover the side surfaces of the conductive plugs 104. Namely, the top surfaces 104a and the bottom surfaces 104b of the conductive plugs 104 are not covered by the substrate 100. The uncovered top surfaces 104a and bottom surfaces 104b of the conductive plugs 104 are to be electrically connected to other wafers or chips in subsequent processes.

Similarly, if the polishing process is performed for a long period of time, the oxide material layer 112 can be removed to a great extent, so as to form the structure shown in FIG. 1E. Namely, in FIG. 1E, both the top surfaces 104a of the conductive plugs 104 and a portion of the side surfaces close to the top surfaces 104a of the conductive plugs 104 are exposed.

In light of the foregoing, the thinning process performed on the back surface of the substrate does not cause the conductive plugs to be exposed according to this disclosure. As a matter of fact, after the thinning process is performed to some degree, the oxide material layer is formed on the back surface of the substrate to cover the conductive plugs. The polishing process is then carried out to expose the conductive plugs. That is to say, the conductive plugs of this disclosure are covered by the oxide material layer. Accordingly, when the polishing process is subsequently performed to expose the conductive plugs, the metal ions/atoms in the conductive plugs are not diffuse to the substrate, thus preventing the contamination. Particularly, according to this disclosure, the special electro-etching process is performed to form the porous film. The electro-oxidization process is then performed, and the porous film correspondingly reacts to form the oxide material layer. A low temperature annealing process (100° C.˜300° C.) can then be performed on the oxide material layer, such that the oxide material layer can have a dense structure. As a result, the oxide material layer of this disclosure astoundingly precludes the metal ions/atoms in the conductive plugs from diffusing.

Although the disclosure has been described with reference to the above embodiments, it will be apparent to one of the ordinary skill in the art that modifications to the described embodiment may be made without departing from the spirit of the disclosure. Accordingly, the scope of the disclosure will be defined by the attached claims not by the above detailed descriptions.

What is claimed is:

1. A manufacturing method of a semiconductor structure, comprising:
providing a substrate, the substrate having a front surface and a back surface, the front surface having a device layer thereon and a plurality of conductive plugs electrically connected to the device layer;
performing a thinning process on the back surface of the substrate, wherein the back surface of the substrate and surfaces of the conductive plugs have a distance therebetween after performing the thinning process;
forming a plurality of holes in the substrate from the back surface to the conductive plugs, so as to form a porous film;
performing an oxidization process, such that the porous film is correspondingly reacted to form an oxide material layer; and
performing a polishing process on the oxide material layer to expose the surfaces of the conductive plugs.

2. The manufacturing method as claimed in claim 1, a method of forming the porous film comprising:
placing the substrate into an etchant and performing an electro-etching process, such that the back surface of the substrate is etched by the etchant along a crystal orientation direction of the substrate to form the holes.

3. The manufacturing method as claimed in claim 2, wherein a concentration of the etchant is about 2% to about 20%, the etchant comprises hydrofluoric acid or hydrofluoric acid containing an oxidizing agent, and the electro-etching process is performed for about 2 minutes to about 60 minutes at a normal temperature.

4. The manufacturing method as claimed in claim 2, wherein a diameter of the holes is about 0.001 um to about 1 um, and a depth of the holes is about 0.5 um to about 10 um.

5. The manufacturing method as claimed in claim 1, a method of forming the porous film comprising:
forming a plurality of conductive particles on the back surface of the substrate; and
placing the substrate into an etchant and performing an electro-etching process, such that the back surface of the substrate is etched by the etchant along the conductive particles to form the holes.

6. The manufacturing method as claimed in claim 5, a method of forming the conductive particles comprising performing a chemical displacement process.

7. The manufacturing method as claimed in claim 6, wherein the chemical displacement process is performed on condition that the back surface of the substrate is exposed to a TaClx-containing water solution or a TiCly-containing water solution at about 20° C. to about 60° C. for about 1 minute to about 30 minutes, x=2˜5, and y=2˜4.

8. The manufacturing method as claimed in claim 5, wherein a concentration of the etchant is about 2% to about 20%, the etchant comprises hydrofluoric acid or hydrofluoric acid containing an oxidizing agent, and the electro-etching process is performed for about 2 minutes to about 60 minutes at a normal temperature.

9. The manufacturing method as claimed in claim 5, wherein a diameter of the holes is about 0.001 um to about 1 um, and a depth of the holes is about 0.5 um to about 15 um.

10. The manufacturing method as claimed in claim 1, the oxidization process comprising:
placing the substrate into an alkaline solution having a reference electrode; and
respectively applying a voltage to the reference electrode and the substrate, such that a difference in potential is between the substrate and the reference electrode, and that ions in the alkaline solution react with the porous film to form the oxide material layer.

11. The manufacturing method as claimed in claim 10, wherein a concentration of the alkaline solution is about 0.001 M to about 1 M, and the alkaline solution comprises sodium hydroxide, potassium hydroxide, or ammonium hydroxide.

12. The manufacturing method as claimed in claim 1, wherein the distance between the back surface of the substrate and the surfaces of the conductive plugs is about 1 um to about 3 um.
